(19) United States
(12) Patent Application Publication
(10) Pub. No.: US 2019/0207315 A1
(43) Pub. Date: Jul. 4, 2019

(54) ANTENNA AND METHOD FOR MANUFACTURING THE SAME

(71) Applicants: ELECTRONICS AND TELECOMMUNICATIONS RESEARCH INSTITUTE, Daejeon (KR); Korea Advanced Institute of Science and Technology, Daejeon (KR); Center for Advanced Meta-Materials, Daejeon (KR)

(72) Inventors: Won Kyu CHOI, Daegu (KR); Jonghwa SHIN, Daejeon (KR); Hak-Ju LEE, Daejeon (KR); MI HYUN KIM, Daejeon (KR); Taeyong CHANG, Daejeon (KR); Sunghoon HONG, Daejeon (KR)

(21) Appl. No.: 16/047,321

(22) Filed: Jul. 27, 2018

(30) Foreign Application Priority Data
Jan. 4, 2018 (KR) 10-2018-0001029
Jul. 9, 2018 (KR) 10-2018-0079356

(51) Int. Cl. H01Q 9/04; H01Q 9/16; H03H 7/38; H01Q 1/38

(52) U.S. Cl. CPC H01Q 9/0442; H01Q 1/38; H03H 7/38; H01Q 9/16

(57) ABSTRACT

An antenna and a method of manufacturing the antenna. The antenna includes an antenna structure, and a metamaterial that has a high dielectric constant and that includes metal patterns arranged at regular intervals.

### CROSS-REFERENCE TO RELATED APPLICATION(S)

This application claims the priority benefit of Korean Patent Application No. 10-2018-0001029, filed Jan. 4, 2018, and Korean Patent Application No. 10-2018-0079356, filed Jul. 9, 2018, in the Korean Intellectual Property Office, the disclosure of which is incorporated herein by reference for all purposes.

### BACKGROUND

### 1. Field of the Invention

One or more example embodiments relate to an antenna, and more particularly, to a subminiature antenna using a metamaterial with a high dielectric constant.

### 2. Description of Related Art

An antenna performs conversion between electric signals represented by voltage and current and electromagnetic waves represented by an electric field and a magnetic field. A change in an electromagnetic field outside the antenna and an electrical signal on an antenna conducting wire may interact with each other so that the antenna may detect an electromagnetic wave signal floating in the atmosphere or may emit an electromagnetic wave signal to the atmosphere.

### SUMMARY

Example embodiments provides an antenna that may achieve a miniaturization of a dipole antenna based on a metamaterial with a high dielectric constant, the dipole antenna and a unique arrangement structure of a matching structure.

According to an aspect, there is provided an antenna including an antenna structure, and a metamaterial with a high dielectric constant, the metamaterial including metal patterns arranged at regular intervals.

The metamaterial may include a plurality of thin film dielectrics that are laminated. Each of the plurality of thin film dielectrics may include the metal patterns arranged at regular intervals.

A first metal cell forming a metal pattern included in a first thin film dielectric, and a second metal cell forming a metal pattern included in a second thin film dielectric adjacent to the first thin film dielectric may be spaced apart by a predetermined interval in a direction parallel to the second thin film dielectric.

The predetermined interval may correspond to half of a width of the second metal cell.

A dielectric between a plurality of metal cells forming one of the metal patterns may have insulating properties.

The antenna structure may include a dipole antenna formed on one side of the antenna structure, and a matching structure formed on another side of the antenna structure.

The dipole antenna may be formed on one side of a thin polyethylene terephthalate (PET) film, and the matching structure may be formed on another side of the thin PET film.

The matching structure may be a metal with a loop structure.

The dipole antenna may have a capacitive impedance characteristic, and the matching structure may have an inductive impedance characteristic.

According to another aspect, there is provided a method of manufacturing an antenna, the method including forming metal patterns at regular intervals in each of a plurality of thin film dielectrics, forming a metamaterial with a high dielectric constant by laminating the plurality of thin film dielectrics, and combining the metamaterial with an antenna structure.

The forming of the metal patterns may include printing metal patterns at regular intervals on each of the plurality of thin film dielectrics using a printed circuit board (PCB) process.

The method may further include forming the antenna structure. The forming of the antenna structure may include forming a dipole antenna on one side of a thin PET film, and forming a matching structure on another side of the thin PET film.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating an overall configuration of an antenna according to an example embodiment;

FIG. 2 is a diagram illustrating a meta structure in a thin film dielectric according to an example embodiment;

FIG. 3 is an x-y plane view illustrating a meta structure in a thin film dielectric according to an example embodiment;

FIG. 4 is an x-z plane view illustrating a meta structure in a thin film dielectric according to an example embodiment;

FIG. 5 is a diagram illustrating a structure of an antenna according to an example embodiment;

FIG. 6A illustrates a Smith chart representing a characteristic of an input impedance of an antenna according to a related art, and 6B illustrates a Smith chart representing a characteristic of an input impedance of an antenna according to an example embodiment;

FIG. 7 is a graph illustrating a characteristic of a return-loss bandwidth of an antenna according to an example embodiment; and

FIG. 8 is a flowchart illustrating a method of manufacturing an antenna according to an example embodiment.

### DETAILED DESCRIPTION

The following structural or functional descriptions of example embodiments described herein are merely intended for the purpose of describing the example embodiments described herein and may be implemented in various forms. However, it should be understood that these example embodiments are not construed as limited to the illustrated forms.

Although terms of “first,” “second,” and the like are used to explain various components, the components are not limited to such terms. These terms are used only to distinguish one component from another component. For example, a first component may be referred to as a second component, or similarly, the second component may be referred to as the first component within the scope of the present disclosure.

When it is mentioned that one component is “connected” to another component, it may be understood that the one component is directly connected or accessed to another component or that still other component is interposed between the two components.

As used herein, the singular forms are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, example embodiments will be described in detail with reference to the accompanying drawings. The scope of the right, however, should not be construed as limited to the example embodiments set forth herein. Like reference numerals in the drawings refer to like elements throughout the present disclosure.

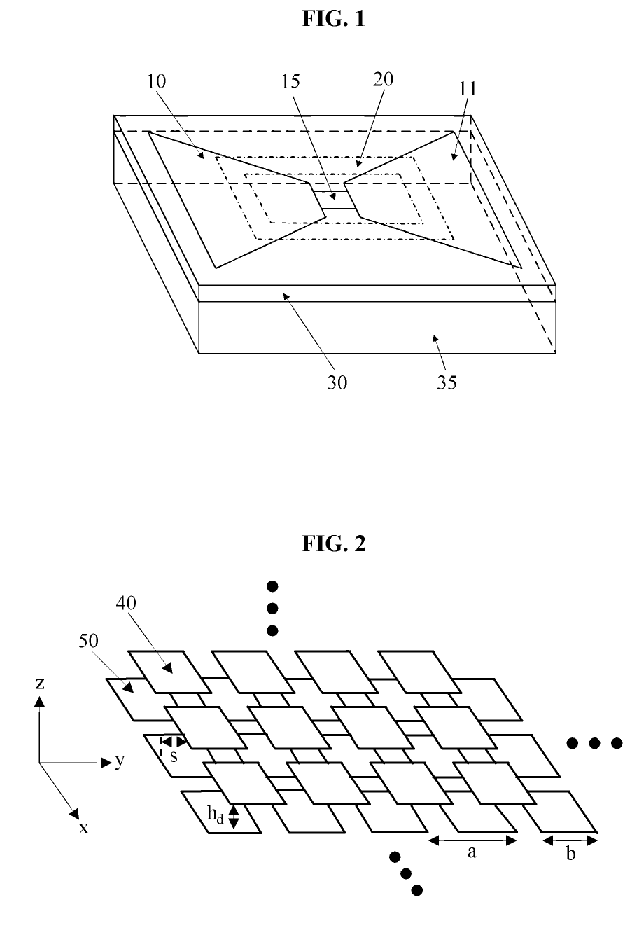

FIG. 1 is a diagram illustrating an overall configuration of an antenna according to an example embodiment.

Referring to FIG. 1, the antenna includes an antenna structure 30 and a metamaterial 35 with a high dielectric constant. The metamaterial 35 may include metal patterns arranged at regular intervals.

The metamaterial 35 and the antenna structure 30 may be combined to implement a subminiature antenna. The metamaterial 35 may include a thin film dielectric that includes metal patterns arranged at regular intervals. The antenna structure 30 may include a dipole antenna and a matching structure 20. The dipole antenna may include a left pole 10, a right pole 11 and a power feeder 15.

The metamaterial 35 may form metal patterns at regular intervals in a thin film dielectric, and may be formed by laminating a plurality of thin film dielectrics. The formed metamaterial 35 may have a characteristic of a high dielectric constant. For example, the metamaterial 35 may have a relative permittivity of “200” to “300.”

Since the metal patterns are formed at regular intervals in the thin film dielectric, an electric field localization may occur. Due to the electric field localization, a strong local electric field may be formed in comparison to a macroscopic effective electric field. Due to the strong local electric field, an effective electric flux density of the metamaterial 35 may be increased. Thus, the metamaterial 35 may have a characteristic of a high dielectric constant.

The antenna structure 30 may implement matching for an antenna function by a unique arrangement structure of the matching structure 20 and the dipole antenna. A resistance component and a reactance component in an input impedance of the antenna structure 30 may be adjusted by the unique arrangement structure of the matching structure 20 and the dipole antenna, to achieve the matching.

FIG. 2 is a diagram illustrating a meta structure in a thin film dielectric according to an example embodiment.

The metamaterial 35 of FIG. 1 may include a plurality of thin film dielectrics that are laminated. Each of the plurality of thin film dielectrics may include metal patterns arranged at regular intervals. A dielectric between a plurality of metal cells 40 and 50 forming one of the metal patterns may have insulating properties.

A metal pattern in the metamaterial 35 may include a plurality of metal cells 40 and 50 arranged at regular intervals in an x direction and a y direction. The plurality of metal cells 40 and 50 may have the same shape and the same size. For example, the plurality of metal cells 40 and 50 may have a rectangular shape.

Metal patterns on an x-y plane may be spaced apart by h_{d} that is an interval in a z direction. When h_{d} decreases, a number of metal patterns included in a predetermined volume may increase, which may lead to a miniaturization of an antenna. Thus, h_{d} may be set as small as possible. An interval between the closest metal cells 40 and 50 included in each of the metal patterns on the x-y plane may be denoted by “s.” Each of the metal patterns on the x-y plane may be shifted by the interval s. The metal cells 40 may form a zigzag pattern with the metal cells 50 on a plane view. For example, the interval s may correspond to half of a width of a metal cell.

Based on an xyz coordinate system of FIG. 2, an electromagnetic wave may propagate in the z direction. A strong polarization of an electric field may occur in the x direction and the y direction by metal patterns arranged at regular intervals. Due to the strong polarization, the relative permittivity of the metamaterial 35 may equivalently increase. Thus, a strong polarization of a local electric field between the metal cells 40 and 50 formed in the metamaterial 35 may occur due to the electromagnetic wave propagating in the z direction, and accordingly the relative permittivity of the metamaterial 35 may increase.

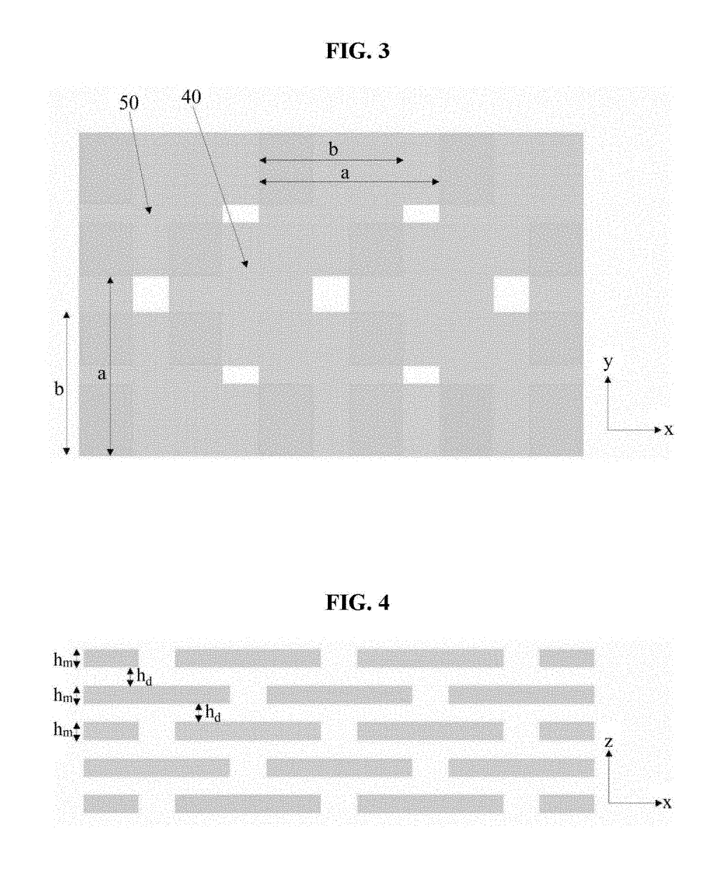

FIG. 3 is an x-y plane view illustrating a meta structure in a thin film dielectric according to an example embodiment, and FIG. 4 is an x-z plane view illustrating a meta structure in a thin film dielectric according to an example embodiment. FIGS. 3 and 4 illustrate, in detail, a three-dimensional (3D) structure of FIG. 2 on an x-y plane and an x-z plane.

According to an example embodiment, a first metal cell may form a metal pattern included in a first thin film dielectric, and a second metal cell may form a metal pattern included in a second thin film dielectric adjacent to the first thin film dielectric. The first metal cell and the second metal cell may be spaced apart by a predetermined interval in a direction parallel to the second thin film dielectric. For example, the predetermined interval may correspond to half of a width of the second metal cell.

Referring to FIG. 3, the metamaterial 35 may have a structure in which metal cells 40 and 50 are three-dimensionally repeated. The metal cells 40 and 50 may be spaced apart by a predetermined interval in each of an x direction, a y direction and a z direction. The metal cells 40 and 50 may have the same size. For example, when each of the metal cells 40 and 50 has a square shape, one side of each of the metal cells 40 and 50 may have a length “b,” and an interval between adjacent metal cells 40 and 50 on the x-y plane may be “a-b.”

Referring to FIG. 4, the metamaterial 35 may have a structure in which metal cells 40 and 50 are three-dimensionally repeated. The metal cells 40 and 50 may each have a thickness of hₘ in a z direction, and may be spaced apart by h_{d}. A thickness of each of the metal cells 40 and 50 may be extremely less than that of a right side or a left side of each of the metal cells 40 and 50. A dielectric having insulating properties may be included between the metal cells 40 and 50.

For example, when each of the metal cells 40 and 50 has a square shape, when a length of one side is “b,” when a length from one side of each of the metal cells 40 and 50 to a corresponding side of each of adjacent metal cells 40 and 50 is “a,” when each of the metal cells 40 and 50 has a thickness of hₘ, and when an interval between the metal cells 40 and 50 in a z direction is h_{d}, a dielectric constant ε_{d} may be calculated using the following Equation 1:

$${ɛ}_{eff} = {ϵ}_{d} \frac{{a}^{2}}{4 {h}_{d} ( {h}_{m} + {h}_{d} )} {( \frac{2 b - a}{a} )}^{2} \qquad [ Equation 1 ]$$

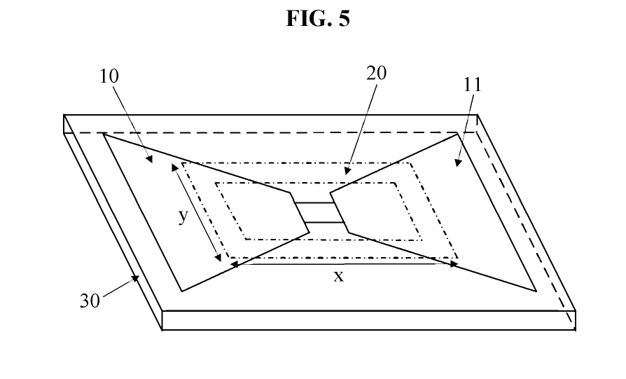

FIG. 5 is a diagram illustrating a structure of an antenna according to an example embodiment.

The antenna structure 30 of FIG. 1 may include the dipole antenna formed on one side, and the matching structure 20 formed on another side. The dipole antenna may include the left pole 10 and the right pole 11. For example, a dipole antenna may be formed on one side of a thin polyethylene terephthalate (PET) film, and a matching structure may be formed on another side of the PET film.

The dipole antenna may be a short dipole. Due to a characteristic of the short dipole, the dipole antenna may exhibit a capacitive impedance characteristic. Since the antenna structure 30 needs to be miniaturized, the matching structure 20 may be formed on a bottom of the PET film.

The dipole antenna may have a capacitive impedance characteristic, and the matching structure 20 may have an inductive impedance characteristic. The matching structure 20 may be a metal having a loop structure. The matching structure 20 may have the inductive impedance characteristic due to the loop structure, and may compensate for the capacitive impedance characteristic of the dipole antenna. By adjusting a width x and a length y of the matching structure 20, a magnitude of an inductive impedance may be controlled. The capacitive impedance characteristic of the dipole antenna may be compensated for by the matching structure 20, and thus matching may be achieved. Therefore, voltage applied to the dipole antenna may resonate.

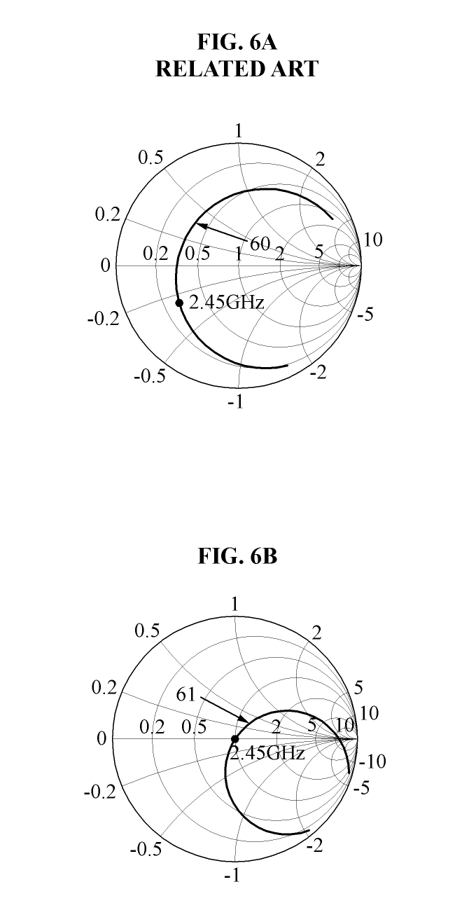

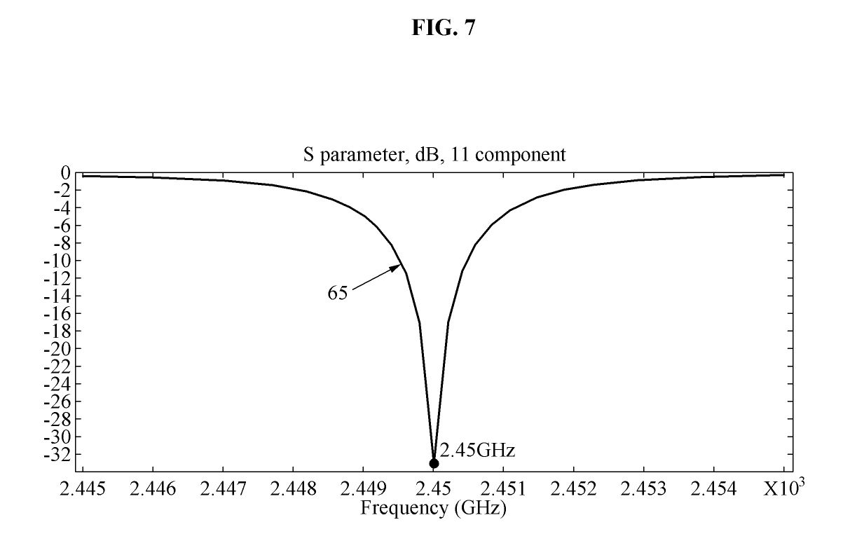

FIG. 6A illustrates a Smith chart representing a characteristic of an input impedance of an antenna according to a related art, and 6B illustrates a Smith chart representing a characteristic of an input impedance of an antenna according to an example embodiment.

The Smith chart of FIG. 6A shows an impedance characteristic 60 of an antenna that does not have a matching structure according to the related art. The Smith chart of FIG. 6B shows an impedance characteristic 61 of an antenna that has a matching structure according to an example embodiment.

For example, the antenna according to the related art may be designed to resonate at 2.45 gigahertz (GHz). Referring to FIG. 6A, the antenna exhibits a capacitive impedance characteristic at 2.45 GHz. FIG. 6B shows the impedance characteristic 61 of the antenna having the matching structure. In FIG. 6B, a capacitive impedance characteristic may be compensated for by a loop-shaped matching structure, so that the antenna may resonate.

FIG. 7 is a graph 65 illustrating a characteristic of a return-loss bandwidth of an antenna according to an example embodiment.

A left pole and a right pole of the antenna may correspond to a broken conducting wire, and thus it is impossible to transmit an electric signal in a broken portion of the conducting wire. The antenna may allow the above two poles to resonate at a specific frequency, and accordingly signals may form energy in a form of an electromagnetic field instead of being returned, so as to emit the energy to an external device.

The antenna may be a 1-port device including only an input port, not an output port, and may have a value of an S11 component that refers to an input reflection coefficient, as shown in FIG. 7. When values of the S11 component form a valley at a specific frequency as shown in the graph 65 of FIG. 7, a radiation efficiency of the antenna may increase and a degree of matching may be evaluated to increase. When a width of the valley of the graph 65 increases, a bandwidth of a frequency that may be accepted by the antenna may be evaluated to increase.

FIG. 7 illustrates the characteristic of the return-loss bandwidth of the antenna. In FIG. 7, the graph 65 shows a characteristic of a bandwidth of about 1 megahertz (MHz) based on −10 dB of a return loss with respect to a resonant frequency of 2.45 GHz.

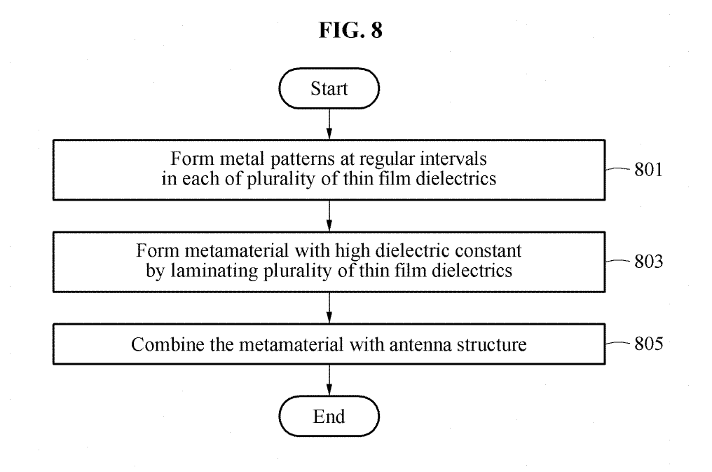

FIG. 8 is a flowchart illustrating a method of manufacturing an antenna according to an example embodiment.

According to an example embodiment, an antenna manufacturing apparatus may form a metamaterial with a high dielectric constant using a low-priced printed circuit board (PCB) process, and may manufacture a subminiature antenna by combining the metamaterial with an antenna structure.

Referring to FIG. 8, in operation 801, the antenna manufacturing apparatus may form metal patterns at regular intervals in each of a plurality of thin film dielectrics. The antenna manufacturing apparatus may print metal patterns at regular intervals on each of the plurality of thin film dielectrics using a PCB process, to form the metal patterns.

In operation 803, the antenna manufacturing apparatus may form a metamaterial with a high dielectric constant by laminating the plurality of thin film dielectrics.

In operation 805, the antenna manufacturing apparatus may combine the metamaterial with the antenna structure. For example, the antenna manufacturing apparatus may form the antenna structure using a PCB process. The antenna manufacturing apparatus may print a dipole antenna on a top of a thin PET film. The antenna manufacturing apparatus may also print a matching structure with a loop shape on a bottom of the thin PET film. When an antenna structure and the matching structure are formed on both surfaces of the thin PET film as described above, the metamaterial may be combined with the antenna structure.

According to example embodiments, it is possible to achieve a miniaturization of a dipole antenna based on a metamaterial with a high dielectric constant, the dipole antenna and a unique arrangement structure of a matching structure.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The modules, apparatuses, and other components described herein may be implemented using a hardware component, a software component and/or a combination thereof. A processing device may be implemented using one or more general-purpose or special purpose computers, such as, for example, a processor, a controller and an arithmetic logic unit (ALU), a DSP, a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An antenna comprising:
an antenna structure; and
a metamaterial with a high dielectric constant, the metamaterial comprising metal patterns arranged at regular intervals.

2. The antenna of claim 1, wherein:
the metamaterial comprises a plurality of thin film dielectrics that are laminated, and
each of the plurality of thin film dielectrics comprises the metal patterns arranged at regular intervals.

3. The antenna of claim 2, wherein a first metal cell forming a metal pattern included in a first thin film dielectric, and a second metal cell forming a metal pattern included in a second thin film dielectric adjacent to the first thin film dielectric are spaced apart by a predetermined interval in a direction parallel to the second thin film dielectric.

4. The antenna of claim 3, wherein the predetermined interval corresponds to half of a width of the second metal cell.

5. The antenna of claim 2, wherein a dielectric between a plurality of metal cells forming one of the metal patterns has insulating properties.

6. The antenna of claim 1, wherein the antenna structure includes a dipole antenna formed on one side of the antenna structure, and a matching structure formed on another side of the antenna structure.

7. The antenna of claim 6, wherein the dipole antenna is formed on one side of a thin polyethylene terephthalate (PET) film, and the matching structure is formed on another side of the thin PET film.

8. The antenna of claim 6, wherein the matching structure is a metal with a loop structure.

9. The antenna of claim 7, wherein the dipole antenna has a capacitive impedance characteristic, and the matching structure has an inductive impedance characteristic.

10. A method of manufacturing an antenna, the method comprising:
forming metal patterns at regular intervals in each of a plurality of thin film dielectrics;
forming a metamaterial with a high dielectric constant by laminating the plurality of thin film dielectrics; and
combining the metamaterial with an antenna structure.

11. The method of claim 10, wherein the forming of the metal patterns comprises printing metal patterns at regular intervals on each of the plurality of thin film dielectrics using a printed circuit board (PCB) process.

12. The method of claim 10, further comprising:
forming the antenna structure,
wherein the forming of the antenna structure comprises forming a dipole antenna on one side of a thin polyethylene terephthalate (PET) film, and forming a matching structure on another side of the thin PET film.
